(19) United States
(12) Patent Application Publication
(10) Pub. No.: US 2011/0049584 A1
(43) Pub. Date: Mar. 3, 2011

(54) SEMICONDUCTOR DEVICE

(75) Inventor: Nobuyuki Momo, Kanagawa-ken (JP)

(73) Assignee: KABUSHIKI KAISHA TOSHIBA, Tokyo (JP)

(21) Appl. No.: 12/845,942

(22) Filed: Jul. 29, 2010

(30) Foreign Application Priority Data
Jul. 29, 2009 (JP) P2009-176763

(51) Int. Cl. H01L 29/78

(52) U.S. Cl. 257/288; 257/E29.255

(57) ABSTRACT

According to one embodiment, a semiconductor device, may include a semiconductor substrate including a first semiconductor layer of a first conductivity type and a second semiconductor layer of a second conductivity type different from the first conductivity type, the first semiconductor having a resistance value in a range from 100 Ω·cm to 10000 Ω·cm, the second semiconductor layer having a resistance value in a range from 100 Ω·cm to 10000 Ω·cm, the second semiconductor layer provided on the first semiconductor layer, a first region being formed in the second semiconductor layer and including a first conductivity type of well region and a second conductivity type of well region, a first insulating layer formed on the second semiconductor layer; and a wiring layer located in a second region different from the first region and constituting a passive device insulated by the first insulating layer, wherein no well region is formed in the second semiconductor layer located in the second region.

### CROSS REFERENCE TO RELATED APPLICATION

This application is based upon and claims the benefit of priority from Japanese Patent Application No. 2009-176763, filed on Jul. 29, 2009, the entire contents of which are incorporated herein by reference.

### BACKGROUND

The recent miniaturization of CMOS devices has led to the development of a technique called RF-CMOS where an RF circuit is fabricated using a CMOS. In an integrated circuit with a CMOS, an analog circuit part is a requisite component. In the RF circuit and the analog circuit, unlike a logic circuit, not only the performance of a transistor but also the performance of a capacitor or an inductor called a passive device is important.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a cross-sectional view of a semiconductor device according to a first embodiment.

FIG. 2 is an equivalent circuit schematic of the semiconductor device shown in FIG. 1.

FIG. 3 is an equivalent circuit schematic of a comparative example of the semiconductor device shown in FIG. 2.

FIG. 4 is a cross-sectional view of a semiconductor device according to a second embodiment.

FIG. 5 is a cross-sectional view of a semiconductor device according to a modification of the second embodiment.

### DETAILED DESCRIPTION

According to one embodiment, a semiconductor device, may include a semiconductor substrate including a first semiconductor layer of a first conductivity type and a second semiconductor layer of a second conductivity type different from the first conductivity type, the first semiconductor having a resistance value in a range from 100 Ω·cm to 10000 Ω·cm, the second semiconductor layer having a resistance value in a range from 100 Ω·cm to 10000 Ω·cm, the second semiconductor layer provided on the first semiconductor layer, a first region being formed in the second semiconductor layer and including a first conductivity type of well region and a second conductivity type of well region, a first insulating layer formed on the second semiconductor layer; and a wiring layer located in a second region different from the first region and constituting a passive device insulated by the first insulating layer, wherein no well region is formed in the second semiconductor layer located in the second region.

A regular CMOS circuit is fabricated on a silicon (Si) substrate of 10 Ω·cm or smaller. For this reason, coupling of an inductor or a transmission line used in an RF circuit to the substrate causes eddy currents to flow in the substrate, resulting in losses. As a result, in the case of the inductor, there may be a problem of a Q-factor decrease.

As measures for solving this, use of a Si substrate which generally has a high resistance value is under consideration. This is because increasing the resistance value of a substrate reduces eddy currents, and reduced substrate coupling improves the Q factor.

However, sufficient decrease of the coupling in a high frequency region of several tens of GHz, for example is difficult through the mere increasing of the substrate resistance value. In addition, the higher the resistance value of a substrate, the higher the cost thereof. Accordingly, in view of both the performance and the cost, it is difficult to prevent performance deterioration of the passive device operating in a high frequency range only by increasing the resistance value of the substrate.

Moreover, a semiconductor device which can achieve a high Q factor in a high frequency circuit by decreasing the parasite capacitance of an inductor has been developed (for example, Japanese Patent Laid Open Publication 2002-94009). Specifically, in this semiconductor device, a high-concentration n+ type diffusion layer is formed under a separation oxide film in a region provided with an inductor, and the parasite capacitance of the inductor is decreased by use of a pn junction of the n+ diffusion layer and a p− type semiconductor substrate. However, when the high-concentration n+ diffusion layer is formed on a surface side of the substrate, the substrate resistance of this part decreases; therefore, eddy currents are caused to flow, and the capacitance of the pn junction does not serve as the parasite capacitance. Thus, no effect can be produced. Further, since the capacitance of a high-concentration junction is large, only a small effect of reducing the parasite capacitance is observed.

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

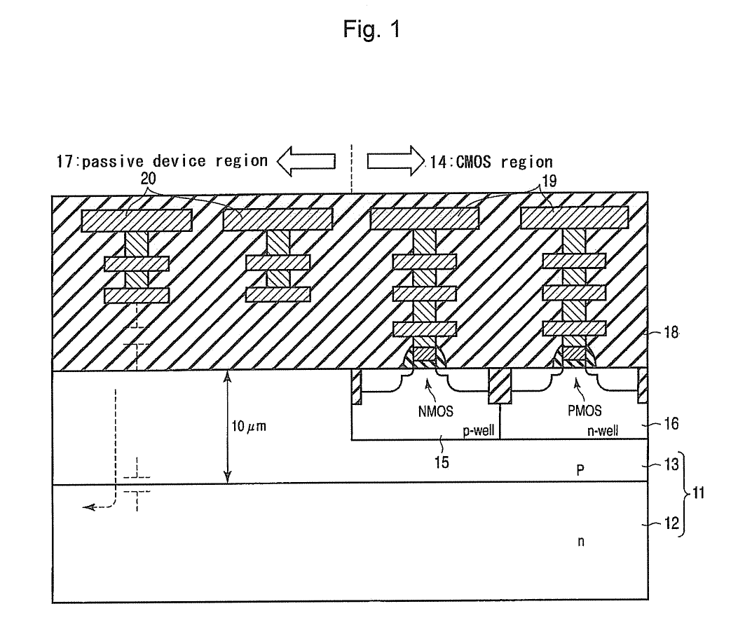

FIG. 1 shows a first embodiment and shows a semiconductor device having, for example, a CMOS circuit and a passive device formed in a multilayered wiring layer.

In FIG. 1, a high-resistant Si substrate 11 has a pn junction. Specifically, in the substrate 11, an n-type layer 12 is formed, and a p-type layer 13 is formed on the n-type layer 12. The thickness of the p-type layer 13 is, for example, 10 μm. A p-type well region 15 and an n-type well region 16 are formed on the p-type layer 13 in a CMOS region 14, whereas no well region is formed on the p-type layer 13 in a passive device region 17. An n channel MOS transistor NMOS is formed in the p-type well region 15, and a p channel MOS transistor PMOS is formed in the n-type well region 16. An interlayer insulating film 18 is formed on the p-type layer 13 both in the CMOS region 14 and in the passive device region 17. Multilayered wiring layers 19 connected to the respective transistors NMOS and PMOS are formed in the interlayer insulating film 18 in the CMOS region 14. Further, a wiring layer 20 is formed in the interlayer insulating film 18 in the passive device region 17. The wiring layer 20 is formed by multilayer wiring, which includes, for example, a metal or a conductive film intended to serve as an inductor or a transmission line.

The p-type layer 13 and the n-type layer 12 have an extremely low impurity concentration. They both have an impurity concentration of, for example, 10¹⁴ cm⁻³ or less. For this reason, the substrate 11 has a high resistance. The resistance value of both the p-type layer 13 and the n-type layer 12 is, for example, in the range from 100 Ω·cm to 10,000 Ω·cm. Specifically, considering, for example, the efficiency of an antenna formed in the passive device region 17, it is assumed that the resistance value needs to be 100 Ω·cm or higher. In addition, the upper limit of the resistance value is 10000 Ω·cm, which is controllable in wafer fabrication.

As described above, the p-type layer 13 located below the wiring layer 20, which is to serve as an inductor or a transmission line, has no well formed therein on the purpose of retaining a high resistance.

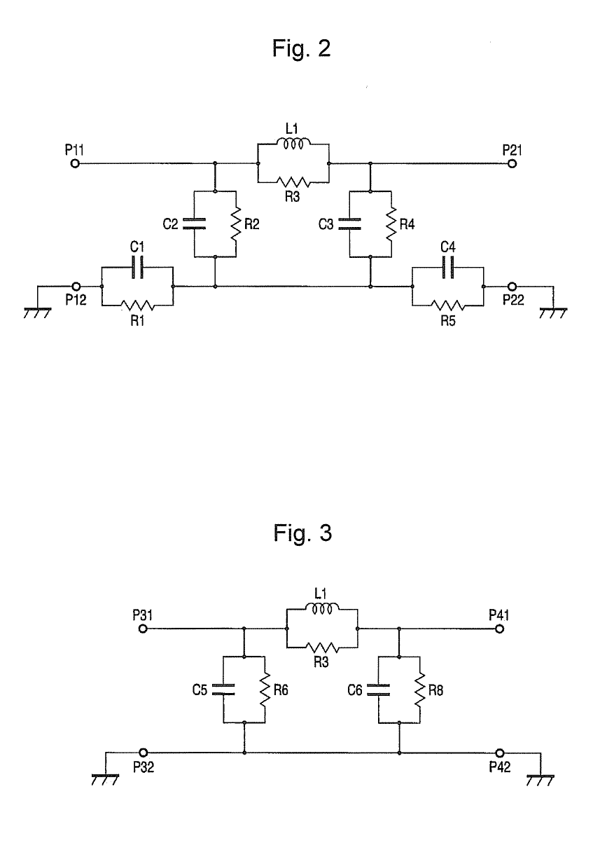

FIG. 2 shows an equivalent circuit schematic of the wiring layer 20, shown in FIG. 1, which serves as an inductor or a transmission line. FIG. 3 shows a comparative example, and shows an equivalent circuit schematic of a wiring layer, which serve as an inductor or a transmission line, in the case where a semiconductor device having the configuration shown in FIG. 1 is fabricated using a substrate having a resistance value of 10 Ω·cm or less.

In FIG. 2, an inductance and a resistance of the wiring layer 20 are denoted by L1 and R3, respectively. Capacitances and resistances between the wiring layer 20 and the p-type layer 13 are denoted by C2, C3 and R2, R4, respectively. Capacitances formed by a pn junction between the p-type layer 13 and the n-type layer 12 of the substrate 11 are denoted by C1, C4, and resistances of the substrate 11 are denoted by R1, R5. The potential of the substrate 11 (the p-type layer 13) under the wiring layer 20 is generally fixed to the ground. For this reason, the substrate potential around the wiring layer 20 is connected to the ground.

Meanwhile, in FIG. 3, capacitances and resistances between the wiring layer 20 and the p-type layer 13 are denoted by C5, C6 and R6, R8, respectively.

As shown in FIG. 3, since the potential of the surface of a substrate having a low resistance value is fixed to the ground, the capacitance of the pn junction in the substrate has no influence as a parasite capacitance. Accordingly, a parallel circuit of the capacitance C5 and the resistance R6 and a parallel circuit of the capacitance C6 and the resistance R8 are directly connected to the ground connected to terminals P32, P42, respectively.

However, with the substrate 11 having a high resistant value shown in FIG. 2, even if the surface of the substrate is to be fixed to the ground, stable potential fixation cannot be achieved for a portion below the wiring layer 20. Accordingly, a path is added by the pn junction in the substrate 11. Specifically, a parallel circuit of the capacitance C1 and the resistance R1 is connected in series between the terminal P12 and a parallel circuit of the capacitance C2 and the resistance R2. Further, a parallel circuit of the capacitance C4 and the resistance R5 is connected in series between the terminal P22 and a parallel circuit of the capacitance C3 and the resistance R4. Since the capacitances C1 and C2 are connected in series, their combined capacity decreases. Since the capacitances C3 and C4 are connected in series as well, their combined capacitance decreases. The value of the junction capacitance C1, C4 is represented in the following expression.

C=εS/d

(ε: relative permittivity, d: the width of depletion layer, S: the area of pn junction)

Being formed by a pn junction of a low impurity concentration, the capacitances C1 and C4 have a large depletion layer width. Accordingly, the value of the junction capacitance C1, C4 is small. Moreover, the combined capacitance of the serially-connected capacitances C1 and C2 and the combined capacitance of the serially-connected capacitances C3, C4 further decrease. Consequently, the parasite capacitance of the substrate 11 and the wiring layer 20 serving as an inductor or a transmission line can be reduced, thereby decreasing coupling losses.

In addition, as described earlier, the resistances R1, R5 of the high-resistant substrate 11 is as high as 100 Ω·cm to 10000 Ω·cm. Moreover, the parasite capacitance of the wiring layer 20 and the substrate 11 is low. Accordingly, the occurrence of eddy currents by coupling of the wiring layer 20 to the substrate 11 can be reduced. Thus, a reduction in Q factor can be prevented, making it possible to improve inductor performances.

According to the first embodiment described above, the resistance value of the substrate 11 having a pn junction inside is set higher than that set for a general substrate, and a well having a high impurity concentration is not formed in the substrate 11 under the wiring layer 20 serving as an inductor or a transmission line. This allows a reduction in the parasite capacitance of the substrate 11 and the wiring layer 20 serving as an inductor or a transmission line, and thereby allows a decrease in coupling losses. Moreover, a decrease in Q factor can be prevented, making it possible to improve inductor performances.

### Second Embodiment

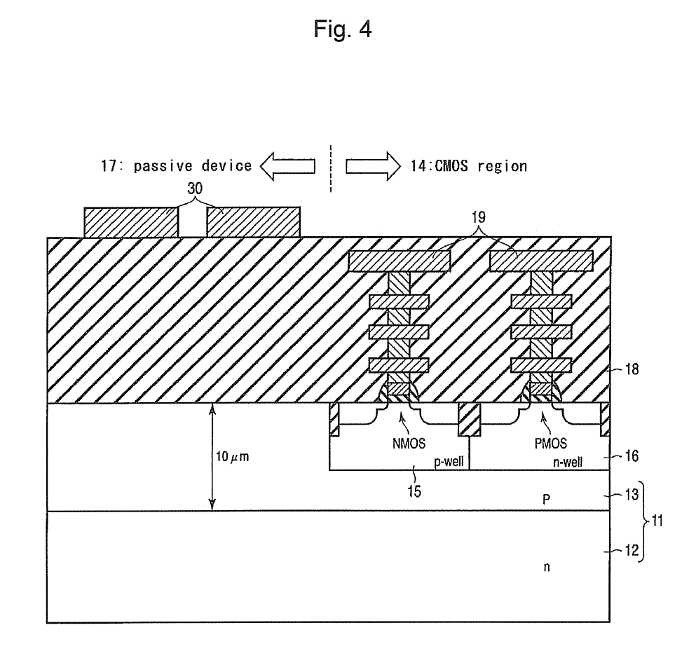

FIG. 4 shows a second embodiment. FIG. 4 shows a case where a passive device is formed using a wiring layer formed at a position higher than the multilayered wiring layer 19. In FIG. 4, the same portions as those in FIG. 1 are denoted by the same reference numerals.

The substrate 11 shown in FIG. 4 includes the n-type layer 12 and the p-type layer 13 on the n-type layer 12. This substrate 11 having a pn junction has a high resistance, like the first embodiment. In the CMOS region 14, the p-type well region 15 and the n-type well region 16 are formed in the p-type layer 13. An NMOS is formed in the p-type well region 15, and a PMOS is formed in the n-type well region 16. The interlayer insulating film 18 is formed above the substrate 11, and the multilayered wiring layers 19 are provided in the interlayer insulating film 18.

Meanwhile, in the passive device region 17, a wiring layer 30 is formed on the interlayer insulating film 18. The wiring layer 30 serves as a passive device, and are formed of a metal or a conductive layer constituting an inductor or a transmission line. A well region having a high concentration impurity is not formed in the p-type layer 13 located below the wiring layer 30. Accordingly, the substrate 11 retains a high resistance.

According to the second embodiment described above, the substrate 11 located below the passive device region 17 has no well region, and therefore is highly resistant. For this reason, the pn junction in the substrate 11 is connected in series, as a parasite capacitance, to a parasite capacitance between the wiring layer 30 and the substrate 11. This allows a reduction in losses due to coupling of the wiring layer 30 and the substrate 11, and prevention of a decrease in Q factor of the inductor.

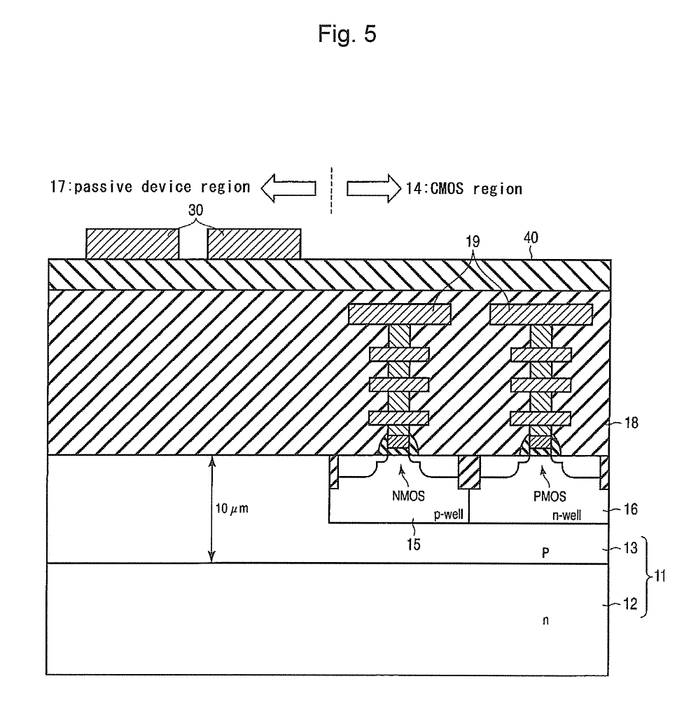

FIG. 5 shows a modification of the second embodiment. In FIG. 5, the same portions as those in FIG. 4 are denoted by the same reference numerals. In the second embodiment, the passive device is formed by using the wiring layer located at a position higher than the multilayered wire layer 19.

In contrast, as shown in FIG. 5, it is also possible to form on the interlayer insulating film 18 an insulating layer 40 by using a material such as, for example, polyimide, and to provide on the insulating layer 40 the wiring layer 30 serving as a passive device and forming, for example, an inductor.

By thus forming the insulating layer 40 on the interlayer insulating film 18 and forming the passive device on the insulating layer 40, coupling losses can be further reduced.

Note that the present invention is not limited to the embodiments given above, and can of course be implemented with various modifications without changing the gist of the present invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

In one aspect, the well has an impurity concentration more than an impurity concentration of a semiconductor substrate. In case no well is provided in a region, the impurity concentration is no more than the impurity concentration of the semiconductor substrate.

What is claimed:

1. A semiconductor device, comprising:
a semiconductor substrate including a first semiconductor layer of a first conductivity type and a second semiconductor layer of a second conductivity type different from the first conductivity type, the first semiconductor having a resistance value in a range from 100 Ω·cm to 10000 Ω·cm, the second semiconductor layer having a resistance value in a range from 100 Ω·cm to 10000 Ω·cm, the second semiconductor layer provided on the first semiconductor layer;
a first region being formed in the second semiconductor layer and including a first conductivity type of well region and a second conductivity type of well region;
a first insulating layer formed on the second semiconductor layer; and
a wiring layer located in a second region different from the first region and constituting a passive device insulated by the first insulating layer, wherein
no well region is formed in the second semiconductor layer located in the second region.

2. The semiconductor device according to claim 1, wherein the wiring layer is formed in the first insulating layer.

3. The semiconductor device according to claim 1, wherein the wiring layer is formed on the first insulating layer.

4. The semiconductor device according to claim 1, further comprising a second insulating layer formed on the first insulating layer, wherein the wiring layer is formed on the second insulating layer.

5. The semiconductor device according to claim 1, wherein an impurity concentration of the first semiconductor layer is no more than 10¹⁴ cm⁻³.

6. The semiconductor device according to claim 1, wherein an impurity concentration of the second semiconductor layer is no more than 10¹⁴ cm⁻³.

7. The semiconductor device according to claim 1, wherein a pn junction between the first semiconductor layer and the second semiconductor layer

8. The semiconductor device according to claim 1, wherein the second semiconductor layer located in the second region has an impurity concentration no more than 10¹⁴ cm⁻³.

9. The semiconductor device according to claim 1, wherein the second semiconductor layer has a thickness of 10 μm.
